(19) United States
(12) Patent Application Publication
(10) Pub. No.: US 2015/0254191 A1
(43) Pub. Date: Sep. 10, 2015

(54) Software Enabled Network Storage Accelerator (SENSA) - Embedded Buffer for Internal Data Transactions

(71) Applicant: Riverscale Ltd, Kfar Saba (IL)

(72) Inventors: Vitaly SUKONIK, Katzir (IL); Evgeny SHUMSKY, Petah Tikva (IL)

(73) Assignee: Riverscale Ltd, Kfar Saba (IL)

(21) Appl. No.: 14/201,969

(22) Filed: Mar. 10, 2014

(51) Int. Cl. G06F 13/16; G06F 13/40; G11C 7/10

(52) U.S. Cl. CPC G06F 13/1673; G11C 7/1072; G06F 13/4068; G06F 13/1663

(57) ABSTRACT

An apparatus and method of bypassing server DRAM by redirecting internal data transactions to an embedded buffer provides an innovative implementation for intermediate storage for internal transactions, providing transparent functionality with improved performance as compared to conventional solutions. Transaction throughput is improved at least in part by avoiding using conventional DRAM, thus eliminating conventional bottlenecks in DRAM intermediate storage. The current embodiment is particularly useful in sending and receiving data blocks between disk storage and network connections.

### FIELD OF THE INVENTION

The present invention generally relates to storing digital data, and in particular, it concerns accelerating network storage of digital data.

### BACKGROUND OF THE INVENTION

Conventional event processing is performed by a general purpose CPU (central processing unit) for processing, retrieving, and returning requested data blocks. Processing is relatively slow, as compared to the processing times demanded of modern users to return requested data, in particular from a remote server/remote storage. There is therefore a need to accelerate network storage of digital data.

### SUMMARY

According to the teachings of the present embodiment there is provided a system including: an array of at least two event processing elements (EPEs), each EPE in the array configured for: receiving events, each of the events having a task corresponding to the event; and processing the task in run-to-completion manner by operating on a first portion of the task and offloading a second portion of the task.

In an optional embodiment, all EPEs in the array are identical. In another optional embodiment, all EPEs in the array are configured with identical instruction code for execution. In another optional embodiment, each EPE in the array is a RISC core. In another optional embodiment, the array of EPEs includes a multitude of EPEs. In another optional embodiment, wherein each the EPE is configured to receive single the events sequentially. In another optional embodiment, each EPE includes firmware configured to implement the operating on the any portion of the task.

In another optional embodiment, the first portion of the task includes functions selected from a group consisting of: classification of received events; deciding on a priority for each received event; arbitrating decisions regarding hardware processing engines (HWEs); and main processing functionality.

In an optional embodiment, the system further includes an event distributor for receiving the events and distributing the events among the EPEs. In another optional embodiment, the event distributor is configured with a round robin tasks dispatcher algorithm to distribute events to each EPE in the array of EPEs.

In an optional embodiment, the system further includes an input events scheduler for: receiving the events as input; scheduling processing of the events; and sending the events as output to the event distributor.

In an optional embodiment, the system further includes an on-chip buffer including at least one memory selected from the group consisting of: an events payload storage memory; and a temporary storage configured for transfers between disk and network wherein each EPE has direct load and store access to the on-chip buffer.

In an optional embodiment, the system further includes an input events queue wherein a number of the EPEs in the array exceeds a maximum number of unclassified events allowed to be waiting to be serviced in the input events queue.

In an optional embodiment, the system further includes a hardware engine module including an array of a plurality of hardware engines (HWEs) configured for processing requests from the EPEs, to which the second portions of the tasks are offloaded.

In an optional embodiment, the HWEs are configured for performing functions selected from the group consisting of: table lookups; internal table lookups; external table lookups; hash calculations; hash SHA-1; hash MD-5; hash AES; link list exploring; session context handling; and transaction context handling;

In an optional embodiment, the system further includes a DRAMs (dynamic random access memory) interface module operationally connected to the hardware engine module and including modules selected from the group consisting of: interface modules; external DRAM interfaces; memories; and internal tables.

In an optional embodiment, the system further includes a volatile memory module operationally connected to the DRAMs interface module and including at least one volatile memory. In another optional embodiment, the volatile memory is a DRAM module.

In an optional embodiment, the system further includes an output actions queues module operationally connected to the array and configured for receiving output from the EPEs. In an optional embodiment, the system further includes an output actions scheduler module operationally connected to the output actions queues module and configured for receiving output from the output actions queues module.

According to the teachings of the present embodiment there is provided a method for processing events including the steps of: receiving events, each of the events having a task corresponding to the event; and processing the task in run-to-completion manner by operating on a first portion of the task and offloading a second portion of the task.

In an optional embodiment, each received event is processed by identical instruction code. In another optional embodiment, each of the events is received sequentially.

In another optional embodiment, the first portion of the task includes functions selected from a group consisting of: classification of received events; deciding on a priority for each received event; arbitrating decisions regarding hardware processing engines (HWEs); and main processing functionality.

In another optional embodiment, the events are received from an event distributor. In another optional embodiment, the event distributor transmits the events based on a round robin tasks dispatcher algorithm. In another optional embodiment, the events are received at the event distributor from an input scheduler configured for: receiving the events as input; scheduling processing of the events; and sending the events as output to the event distributor.

In another optional embodiment, the second portion is offloaded to a hardware engine (HWE) module. In another optional embodiment, the HWE module is configured for performing functions selected from the group consisting of: table lookups; internal table lookups; external table lookups; hash calculations; hash SHA-1; hash MD-5; hash AES; link list exploring; session context handling; and transaction context handling;

In another optional embodiment, processed events are transmitted to an output actions queues module.

According to the teachings of the present embodiment there is provided a computer-readable storage medium having embedded thereon computer-readable code for processing events, the computer-readable code including program code for: receiving events, each of the events having a task corresponding to the event; and processing the task in run-to-completion manner by operating on a first portion of the task and offloading a second portion of the task.

According to the teachings of the present embodiment there is provided a computer program that can be loaded onto a server connected through a network to a client computer, so that the server running the computer program constitutes an array of EPEs in a system according to any one of the above claims.

According to the teachings of the present embodiment there is provided a computer program that can be loaded onto a computer connected through a network to a server, so that the computer running the computer program constitutes an array of EPEs in a system according to any one of the above claims.

According to the teachings of the present embodiment there is provided a system including: a network to disk DMA (NDDMA) module configured as part of a server, the NDDMA including: a network sub-module configured to receive data packets and determine if received data packets are regular data packets or storage data packets; a disk storage sub-module configured to store storage data packets in disk storage; and a transfer sub-module configured to: transfer storage data packets to the disk storage sub-module; and initiate transfer of regular data packets to a component of the system other than the disk storage sub-module.

In an optional embodiment, the NDDMA module further includes an internal temporary buffer configured to receive data packets from the network sub-module and send data packets under control of the transfer sub-module.

In another optional embodiment, the internal temporary buffer is selected from the group consisting of: SENSA DRAMs; temporary storage (308) for transfers between disk and network.

In another optional embodiment, the disk storage sub-module includes logic to communicate with disk controllers. In another optional embodiment, the NDDMA module is implemented by a software enabled network storage accelerator (SENSA) module. In another optional embodiment, the NDDMA module is implemented by a hardware engine (HWE). In another optional embodiment, the transfer sub-module is implemented by an event distributor and power manager (ED/PM). In another optional embodiment, the server is a system on a chip (SoC).

According to the teachings of the present embodiment there is provided a method including the steps of: receiving data packets; determining if received data packets are regular data packets or storage data packets; transferring storage data packets for disk storage; and transferring regular data packets for processing other than disk storage.

An optional embodiment further includes the step of after the receiving data packets, storing the data packets in an internal temporary buffer.

In another optional embodiment, the data packets are received from a network port. In another optional embodiment, the regular data is transferred to a CPU.

According to the teachings of the present embodiment there is provided a server including the NDDMA module.

According to the teachings of the present embodiment there is provided a computer-readable storage medium having embedded thereon computer-readable code, the computer-readable code including program code for: receiving data packets; determining if received data packets are regular data packets or storage data packets; transferring storage data packets for disk storage; and transferring regular data packets for processing other than disk storage.

According to the present embodiment there is provided a system including: (a) at least two event processing elements, each event processing element configured for: (i) receiving events, each event including a respective task, and (ii) for each event, processing only a data access portion of the respective task of the event.

According to the present embodiment there is provided a method of serving requests received as events from a client via a network, each event including a respective task that requires access to disk storage, the method including the steps of: for each task: (a) assigning the task to one of a plurality of event processing elements for processing only a disk storage access portion of the task; (b) by the one event processing element: performing only the disk storage access portion of the task; and (c) by a CPU: performing a remainder of the task.

A basic system of the present embodiment includes two or more event processing elements. Each event processing element is configured for receiving events, each of which includes a respective task, and then processing only a data access portion of the received event's task.

Preferably, the system also includes a plurality of hardware engines to which each event processing element offloads at least a portion of the event processing element's processing. Examples of the kinds of processing that the event processing elements optionally offload to the hardware engines include table lookups (e.g. internal table lookups and/or external table lookups), hash calculations (e.g. hash SHA-1 and/or hash MD-5 and/or hash AES), link list exploring, session context handling, and transaction context handling. More preferably, the system also includes a volatile memory interface module that is operationally connected to the hardware engines and that includes interface sub-modules and/or external interfaces to volatile memories and or memories and/or internal tables. Most preferably, the server also includes a volatile memory module that is operationally connected to the volatile memory interface module and that includes at least one volatile memory such as a DRAM.

Preferably, all the event processing elements are identical.

Preferably, all the event processing elements are configured with identical instruction code for execution.

Preferably, each event processing element is a RISC core.

Preferably, each event processing element is configured to receive single tasks sequentially.

Preferably, each event processing element includes firmware configured to implement at least a portion of the processing. Examples of such portions include classification of received events, deciding on a priority for each received event, arbitrating decisions regarding the hardware engines, and main processing functionality.

Preferably, the system also includes an event distributor for receiving the events and distributing the events among the event processing elements. Most preferably, the event distributor is configured with a round robin tasks dispatcher algorithm to distribute the events among the event processing elements. Also most preferably, the system also includes an input event scheduler for receiving the events as input, for scheduling processing of the events, and for sending the events as output to the event distributor.

Preferably, the system also includes an on-chip buffer that includes at least one memory that may be either an events payload storage memory or temporary storage configured for transfers between the disk storage and the network. Each event processing element has direct load and store access to the on-chip buffer.

Preferably, the system also includes an input events queue. The maximum number of unclassified events allowed to be waiting to be serviced in the input events queue is less than the number of event processing elements.

Preferably, the system also includes an output action queues module that is operationally connected to the event processing elements and that is configured to receive outputs from the event processing elements. Most preferably, the system also includes an output actions scheduler module that is operationally connected to the output action queues module and that is configured to receive output from the output action queues module.

A server of the present embodiment serves requests received as events from a client via a network. Each event includes a respective task. Each task requires access (read access and/or write access) to disk storage. The server includes a network interface card for receiving the events from the network, a system of the present embodiment for processing only the disk storage access portions of the tasks, and a CPU for processing the remainders of the tasks. The system may be included in the network interface card. Alternatively, the system may be included in a co-processor that is separate from the network interface card/

A basic method of the present embodiment is for serving requests that are received as events from a client via a network. Each event includes a respective task that requires access (read access and/or write access) to disk storage. Each task is assigned to one of a plurality of event processing elements for processing only the disk storage access portion of the task. That event processing element then performs only the disk storage access portion of the task. A CPU performs the rest of the task.

According to the teachings of the present embodiment there is provided a system including: an input queue having an instantaneous queue length (IQL) and an average queue length (AQL), the input queue configured for storing incoming events and transmitting the stored events to a tasks distributor configured to receive events from the input queue and distribute events to an array of processing elements configured to receive events from the tasks distributor; having an active portion of zero or more elements in an active-state; and having a sleeping portion of zero or more elements in a sleeping-state, wherein the tasks distributor is additionally configured for: adjusting a size of the active portion based on the AQL.

In an optional embodiment, the input queue is implemented as an input events queue.

Another optional embodiment further includes an elastic buffer configured to receive events from the input queue and transmit events to the tasks distributor. In another optional embodiment, the elastic buffer is implemented as a combination of an input events queue and an input events scheduler.

In another optional embodiment, the tasks distributor is an event distributor and power manager (ED/PM) module. In another optional embodiment, the array of processing elements is an event processing element (EPE) module.

In another optional embodiment, the tasks distributor is additionally configured for the adjusting of the size of the active portion based on a metrics selected from the group consisting of:
(a) anticipated workload;
(b) statistics of pre-classified events;
(c) network port bandwidth monitoring;
(d) instantaneous array utilization of the array of processing elements; and
(e) average array utilization of the array of processing elements.

Another optional embodiment further includes at least one network port bandwidth meter configured to monitor associated at least one network port for received events, wherein the tasks distributor is additionally configured for the adjusting of the size of the active portion based on metrics from the at least one network port bandwidth meter.

In another optional embodiment, the tasks distributor is additionally configured to calculate the AQL as a moving average of the IQL. In another optional embodiment, the tasks distributor is additionally configured to calculate the AQL using the formula: AQL=(1−Wq)*AQL+Wq*IQL where Wq is a relaxing factor less than 0.1.

According to the teachings of the present embodiment there is provided a method for saving power comprising the steps of: receiving events in an input queue having an instantaneous queue length (IQL) and an average queue length (AQL); distributing the events to an array of processing elements, the array of processing elements: having an active portion of zero or more elements in an active-state; and having a sleeping portion of zero or more elements in a sleeping-state, and adjusting a size of the active portion based on the average queue length (AQL).

In an optional embodiment, after receiving, the events are stored in an elastic buffer prior to distributing. In another optional embodiment, the elastic buffer is implemented as a combination of an input events queue and an input events scheduler.

In another optional embodiment, receiving events is to an input events queue. In another optional embodiment, distributing is performed by an event distributor and power manager (ED/PM) module. In another optional embodiment, the array of processing elements is an event processing element (EPE) module.

In another optional embodiment, adjusting the size of the active portion is based on a metric selected from the group consisting of:
(a) anticipated workload;
(b) statistics of pre-classified events;
(c) network port bandwidth monitoring;
(d) instantaneous array utilization of the array of processing elements; and
(e) average array utilization of the array of processing elements.

In another optional embodiment, adjusting of the size of the active portion is additionally based on metrics from at least one network port bandwidth meter.

In another optional embodiment, the AQL is calculated as a moving average of the IQL. In another optional embodiment, the AQL is calculated using the formula: AQL=(1−Wq) AQL+Wq*IQL where Wq is a relaxing factor less than 0.1.

According to the teachings of the present embodiment there is provided a computer-readable storage medium having embedded thereon computer-readable code for saving power, the computer-readable code comprising program code for: receiving events in an input queue having an instantaneous queue length (IQL) and an average queue length (AQL); distributing the events to an array of processing elements, the array of processing elements: having an active portion of zero or more elements in an active-state; and having a sleeping portion of zero or more elements in a sleeping-state, and adjusting a size of the active portion based on the average queue length (AQL).

According to the teachings of the present embodiment there is provided a system including: an embedded buffer configured as part of a server, the embedded buffer including: a temporary storage buffer configured for intermediate storage of transactions; a buffer management module configured for making decisions about subsequent read and write operations to the temporary storage buffer; an arbitration module configured for arbitrating transactions between components of the server; signaling logic providing a handshake mechanism between elements of the embedded buffer and the components of the server.

In an optional embodiment, the server is a system on a chip (SoC). In another optional embodiment, the embedded buffer is memory mapped to be accessible by the components of the server. In another optional embodiment, the transactions come from sources internal or external to the server. In another optional embodiment, the transactions are events.

In another optional embodiment, the temporary storage buffer includes at least two sub-buffers. Another optional embodiment, further includes an event distributor/power manager (ED/PM) configured to control an active portion and sleeping portion of sub-buffers based on a current workload.

In another optional embodiment, the buffer management module is further configured for assisting with queuing and pre-fetching transactions based on operational rates of DRAM, disk, and/or network.
In an optional embodiment, the components are selected from a group consisting of: CPU; SATA; NIC; DMA; and network ports.

In another optional embodiment, the buffer management module and/or the arbitration module are configured to use the signaling logic for control selected from the group consisting of: avoiding overrun conditions in the temporary storage buffer; avoiding underrun conditions in the temporary storage buffer; controlling flow of PCIe; and controlling flow of Ethernet.

According to the teachings of the present embodiment there is provided a method including the steps of: storing transactions in a temporary storage buffer configured in an embedded buffer on a server; deciding to make subsequent read and write operations to the temporary storage buffer based on parameters selected from, but not limited to, a group consisting of: operational rates of DRAM; operational rates of one or more disks; and operational rates of one or more networks, arbitrating transactions between components of the server; and providing signaling logic configured as a handshake mechanism between elements of the embedded buffer and the components of the server.

In an optional embodiment, the embedded buffer is memory mapped to be accessible by the components of the server. In another optional embodiment, the transactions come from sources internal or external to the server. In another optional embodiment, the transactions are events.

In another optional embodiment, the temporary storage buffer includes at least two sub-buffers and further including the step of: controlling an active portion and sleeping portion of sub-buffers based on a current workload.

In another optional embodiment, the step of deciding to make subsequent read and write operations further includes assisting with queuing and pre-fetching transactions.

In another optional embodiment, components are selected from a group consisting of: CPU; SATA; NIC; DMA; and network ports.

In another optional embodiment, the deciding to make subsequent read and write operations uses the signaling logic for control selected from the group consisting of: avoiding overrun conditions in the temporary storage buffer; avoiding underrun conditions in the temporary storage buffer; controlling flow of PCIe; and controlling flow of Ethernet.

According to the teachings of the present embodiment there is provided a computer-readable storage medium having embedded thereon computer-readable code, the computer-readable code including program code for: storing transactions in a temporary storage buffer configured in an embedded buffer on a server; deciding to make subsequent read and write operations to the temporary storage buffer based on parameters selected from, but not limited to, a group consisting of: operational rates of DRAM; operational rates of one or more disks; and operational rates of one or more networks, arbitrating transactions between components of the server; and providing signaling logic configured as a handshake mechanism between elements of the embedded buffer and the components of the server.

According to the present embodiment there is provided a server for serving requests received as events from a client via a network, each event including a respective task, each task requiring access to disk storage, the server including: (a) at least one processor for processing each task in a run-to-completion manner; and (b) a plurality of hardware engines to which each at least one processor offloads at least a portion of the processing of at least one respective the task.

According to the teachings of the present embodiment there is provided a method of serving requests received as events from a client via a network, each event including a respective task that requires access to disk storage, the method including the steps of: (a) providing: (i) at least one processor, and (ii) a plurality of hardware engines; and (b) for each task: (i) assigning the each task to a respective one of the at least one processor, and (ii) by the respective processor: processing the each task in a run-to-completion manner, at least a portion of the processing being offloaded to at least one of the hardware engines.

A server of the present embodiment serves requests received as events from a client via a network. Each event includes a respective task. Each task requires access (read access and/or write access) to disk storage.

A basic server of the present embodiment includes one or more processors for processing each task in a run-to-completion manner, and a plurality of hardware engines to which each processor offloads at least a portion of its processing of at least one of its respective tasks. Preferably, the server includes two or more such processors. Most preferably, the processors are event processing elements.

In embodiments in which the processors are event processing elements:

Preferably, all the event processing elements are identical.

Preferably, all the event processing elements are configured with identical instruction code for execution.

Preferably, each event processing element is a RISC core.

Preferably, each event processing element is configured to receive single tasks sequentially.

Preferably, each event processing element includes firmware for the processing of at least a portion of at least one of the event processing element's respective tasks. Examples of such task portions include classification of received events, deciding on a priority for each received event, arbitrating decisions regarding the hardware engines, and main processing functionality.

In embodiments that include two or more processors (not necessarily event processing elements):

Preferably, the server also includes an event distributor for receiving the events and distributing the events among the processors. Most preferably, the event distributor is configured with a round robin tasks dispatcher algorithm to distribute the events among the processors. Also most preferably, the server also includes an input event scheduler for receiving the events as input, for scheduling processing of the events, and for sending the events as output to the event distributor.

Preferably, the server also includes an on-chip buffer that includes at least one memory that may be either an events payload storage memory or temporary storage configured for transfers between the disk storage and the network. Each processor has direct load and store access to the on-chip buffer.

Preferably, the server also includes an input events queue. The maximum number of unclassified events allowed to be waiting to be serviced in the input events queue is less than the number of processors.

Preferably, the server also includes an output action queues module that is operationally connected to the processors and that is configured to receive outputs from the processors. Most preferably, the server also includes an output actions scheduler module that is operationally connected to the output action queues module and that is configured to receive output from the output action queues module.

In embodiments with any number of processors:

Preferably, the hardware engines are configured to perform table lookups (e.g. internal table lookups and/or external table lookups), hash calculations (e.g. hash SHA-1 and/or hash MD-5 and/or hash AES), link list exploring, session context handling, and/or transaction context handling.

Preferably, the server also includes a volatile memory interface module that is operationally connected to the hardware engines ant that includes interface sub-modules and/or external interfaces to volatile memories and or memories and/or internal tables. Most preferably, the server also includes a volatile memory module that is operationally connected to the volatile memory interface module and that includes at least one volatile memory such as a DRAM.

Preferably, the server also includes a network interface card for receiving the events from the network. The processor(s) and the hardware engines may be included in the network interface card or may be included in a co-processor that is separate from the network interface card.

A basic method of the present embodiment is for serving requests received as events from a client via a network. Each event includes a respective task. Each task requires access (read access and/or write access) to disk storage. One or more processors and a plurality of hardware engines are provided. Each task is assigned to the processor, or to a respective one of the processors if there are more than one processor. The processor to which the task has been assigned processes the task in a run-to-completion manner, with at least a portion of the processing being offloaded to one or more of the hardware engines.

### BRIEF DESCRIPTION OF FIGURES

FIG. 1 is an exemplary reference diagram of retrieving of data over a network.

FIG. 2 is a high-level diagram of an exemplary Software Enabled Network Storage Accelerator (SENSA) implementation.

FIG. 3 is a more detailed diagram of an exemplary Software Enabled Network Storage Accelerator (SENSA) implementation.

FIG. 4 is a high-level partial block diagram of an exemplary system configured to implement a server of the present invention.

FIG. 5 is the high-level SENSA diagram of FIG. 2 additionally showing implementation of an embedded buffer.

### ABBREVIATIONS AND DEFINITIONS

For convenience of reference, this section contains a brief list of abbreviations, acronyms, and short definitions used in this document. This section should not be considered limiting. Fuller descriptions can be found below, and in the applicable Standards. Bold entries are generally specific to the current description.

ACK—Acknowledgement

BW—Bandwidth.

CISC—Complex instruction set computing.

CPU—Central processing unit.

DB—Database.

DMA—Direct memory access.

DRAM—Dynamic RAM (random access memory).

E/PM—Event distributor and power manager module.

EPE—Event processing element module.

Event—Payload of a received packet, explicitly or implicitly requesting the performance of an associated task.

HANA—“High Performance Analytic Appliance”, an in-memory, column-oriented, relational database management system developed and marketed by SAP AG.

HASH, hash—an algorithm that maps data of variable length to data of a fixed length. The values returned by a hash function are called hash values, hash codes, hash sums, checksums, or simply hashes.

HW—Hardware.

HWE, HW engine—Hardware engine.

I/F—Interface.

I/O, IO—Input/output.

IP—Internet protocol.

L1, L2, L3, L4, L5, L6, L7—levels of the OSI (open systems interconnect) networking model.

LAN—Local area network.

MAC—Media access control. Can be an OSI L2 protocol.

MD5—A type of hash algorithm.

MTU—Maximum transmission unit. The largest number of bytes of payload data a frame can carry, not counting the frame's header and trailer.

NDDMA—Network-disk DMA (direct memory access).

NIC—Network interface card.

NPU—Network Processing Unit.

OSI—Open systems interconnect.

PCIe—PCI Express (peripheral component interconnect express), a high-speed serial computer expansion bus standard.

RAM—Random access memory

RD—Read.

RDMA—Remote DMA (direct memory access). A network offload engine. Enables a network adapter to transfer data directly to or from application memory, eliminating the need to copy data between application memory and the data buffers in the operating system.

RISC—Reduced instruction set computing.

RoCE—RDMA over converged Ethernet. A network offload engine. A link layer (L2) network protocol that allows remote direct memory access over an Ethernet network.

RTOS—Real time operating system.

SAS—Serial Attached SCSI. A point-to-point serial protocol that moves data to and from computer storage devices. Offers backward compatibility with some versions of SATA.

SATA—Serial ATA (advance technology attachment). A computer bus interface that connects host bus adapters to mass storage devices such as hard disk drives and optical drives.

SENSA—Software Enabled Network Storage Accelerator.

SHA-1—A type of hash algorithm.

SoC—System on a chip.

SVOE—Storage virtualization offload engine.

SW—Software.

TCP—Transmission control protocol.

TOE—TCP offload engine. A network offload engine used in network interface cards (NICs) to offload processing of the entire TCP/IP stack to a network controller.

WAN—Wide area network.

Wi-Fi, WiFi, WIFI—Wireless local area network (WLAN) products that are based on the Institute of Electrical and Electronics Engineers' (IEEE) 802.11 standards.

WLAN—Wireless local area network (LAN).

WR—Write.

### DETAILED DESCRIPTION

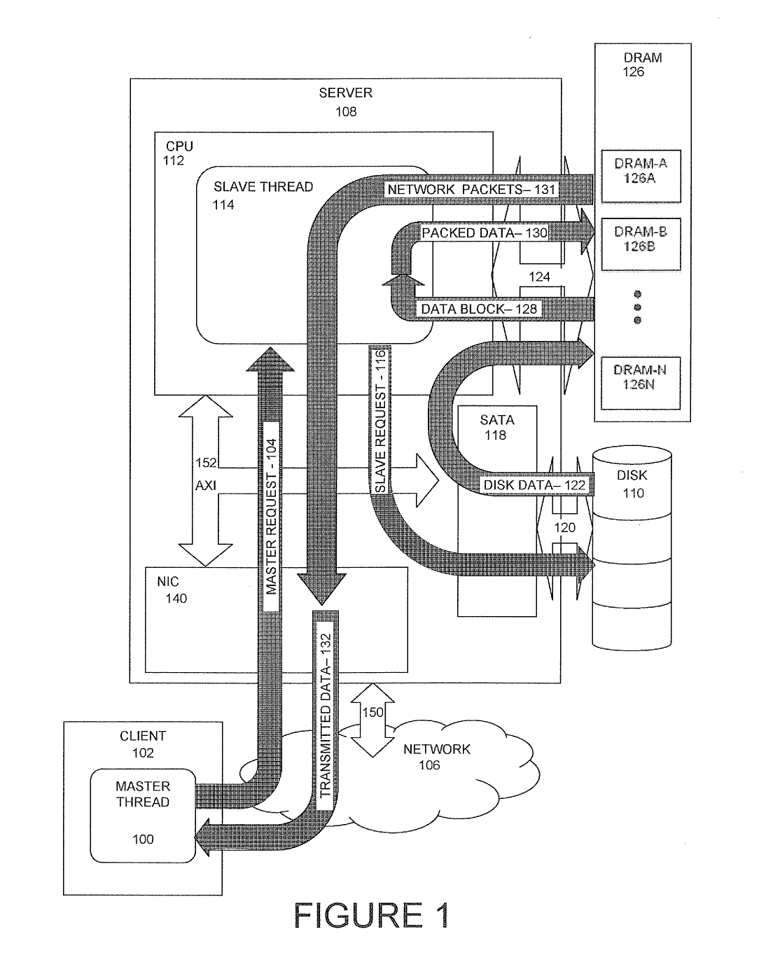

### FIGS. 1 to 5

The principles and operation of the system according to a present embodiment may be better understood with reference to the drawings and the accompanying description. A present invention is a system and methods for accelerating network storage of digital data.

In the context of this document, references to SENSA in general are to the general SENSA system that includes a number of SENSA components. The innovative SENSA components can be implemented individually or in combination. References to SENSA processing generally refer to processing by one or more SENSA components, as will be obvious from the context to one skilled in the art.

The SENSA architecture and components are suitable for a variety of applications, in particular, data base acceleration, disk caching, and event stream processing applications.

Referring now to the drawings, FIG. 1 is an exemplary reference diagram of retrieving of data over a network. For clarity and simplicity in the current description, a typical case is used of a master thread 100 (also known as a client application or user application) on a client machine 102 requests data (master request 104) via a network 106 from a remote server 108 having associated storage (disk 110). The master request 104 is received at the server 108 by a NIC 140 and passed to CPU 112 running a slave thread 114 (also known as a server application). In general, processes are performed by the slave thread 114 using system calls as necessary to access the networking and storage stacks of the operating system (OS). Based on the received master request 104, the slave thread 114 generates and sends a slave request 116 to a SATA 118. The SATA accesses disk 110 via a SATA-disk connection 120 to retrieve the requested data. The SATA sends the retrieved disk data 122 via CPU 112 and CPU-DRAM connection 124 to a DRAM 126. A data block 128 is retrieved from DRAM 126 via CPU-DRAM connection 124, packed in the CPU 112 into packed data 130, and re-stored via CPU-DRAM connection 124 to DRAM 126. The packed data 130 is sent as network packets 131 to the NIC 140 for transmission as transmitted data 132 via the network 106 to the master thread 100 on the client 102. Server 108 includes one or more LAN connections 150 between the server and external networks (such as network 106) for receiving (such as master request 104), transmitting, (such as transmitted data 132), and other known networking functions. Server 108 also can include an internal bus 152 (such as an AXI bus in case of System-On-a-Chip—shown in the figure, or a PCIe bus in the case of a conventional server).

Data retrieval can begin with a remote request for data, in this case with a remote application (represented by master thread 100), sending a request for data (master request 104). On the server 108, receiving the master request 104 initiates invocation of the CPU client (slave thread 114). Typically, the CPU is interrupted and a network stack is generated for the disk block request. The slave thread 114 uses the CPU for hashing data received in the master request 104, in particular hashing the logical address of the data being requested. The resulting hashed value(s) are used via CPU-DRAM connection 124 to do a lookup in an address table in the DRAM 126. The lookup deter mines the physical address of the block(s) of data on disk 110. The physical address(s) of the data block(s) are sent as slave request 116 to the SATA 118. In a case of a disk cache query, the CPU 112 can return a data base lookup status using accesses over 124 to DRAM 126, without using SATA 118. Using the SATA-disk connection 120, the data is retrieved by the SATA 118 and sent to CPU 112. This data retrieved from the disk is shown in the current figure as disk data 122. CPU 112 passes the disk data 122 via CPU-DRAM connection 124 to DRAM 126 for temporary storage and processing. The CPU 112 (slave thread 114) retrieves a portion of the disk data as a data block 128 from the DRAM 126 via the CPU-DRAM connection 124 and processes the data block 128 into network packets, shown in the current figure as packed data 130. The packed data 130 is stored via the CPU-DRAM connection 124 back onto the DRAM 126. The CPU 112 now retrieves the packed data as network packets 131 via the CPU-DRAM connection 124 and passes the network packets 131 to the NIC 140. NIC 140 transmits the network packets 131 as transmitted data 132 via network 106 to the master thread 100 on client 102.

While a typical case is described having the master thread 100 on a client 102 remote from the server 108, one skilled in the art will realize that the master thread 100 can be implemented as a module in other locations, such as on server 108, on CPU 112, or on another CPU in server 108. For simplicity, a single CPU 112 is shown in server 108. Current server technology typically includes multiple CPUs (processors), and one skilled in the art will realize that CPU 112 represents one or more processors. Slave thread 114 can be implemented as a module on a single CPU, or distributed across multiple CPUs. SATA 118 is one technology used to provide access (interface, data transfer) between the CPU 112 and disk 110. Other technologies can be used additionally or alternatively to provide equivalent SATA capability, such as SAS. Similar to the use of CPU 112, as described above, and DRAM 126, as described below, in the context of this document disk 110 is used for simplicity to refer to one or more storage devices. Typically, disk 110 includes one or more hard drives operationally connected to server 108 via an appropriate interface (such as SATA 118).

In the context of this document, DRAM 126 generally refers to a system of one or more DRAMs. Typically, DRAM 126 includes a plurality of DRAMs, shown in the current figure as DRAM-A 126A, DRAM-B 126B, up to and including DRAM-N 126N, where “N” is an integer number greater than zero. CPU-DRAM connection 124 includes one or more connections between CPU 112 and DRAM 126, typically a plurality of parallel connections. Conventional DRAM 126 is typically shared among multiple processors and CPUs. As a result, the number of connections implemented in CPU-DRAM connection 124 from an individual CPU to an individual DRAM is limited. For example, a typical CPU-DRAM connection 124 is to have six connections from the CPU 112 to each DRAM (126A, 126B, 126N). Conventional DRAM 126 is used for functions such as storing tables allowing data to metadata lookups. In typical state-of-the-art implementations, a CPU assumes that most accesses are to cached data (to the cache, and not to DRAM). As a result of this conventional design, while access to cached data is optimized, access to DRAM is relatively slower (longer times, increased latency). As can be seen from the current example, conventional data retrieval via a CPU requires multiple accesses to DRAM, resulting in relatively long latencies as compared to locally accessing cached data.

Network 106 can be any network appropriate for a remote storage application, including but not limited to the Internet, an interne, a local area network (LAN), wide area network (WAN), wireless LAN (WLAN) such as WiFi, etc.

While the current exemplary case describes operation for data retrieval, based on this description one skilled in the art will understand the complementary case of data storage, and be able to implement embodiments for data storage.

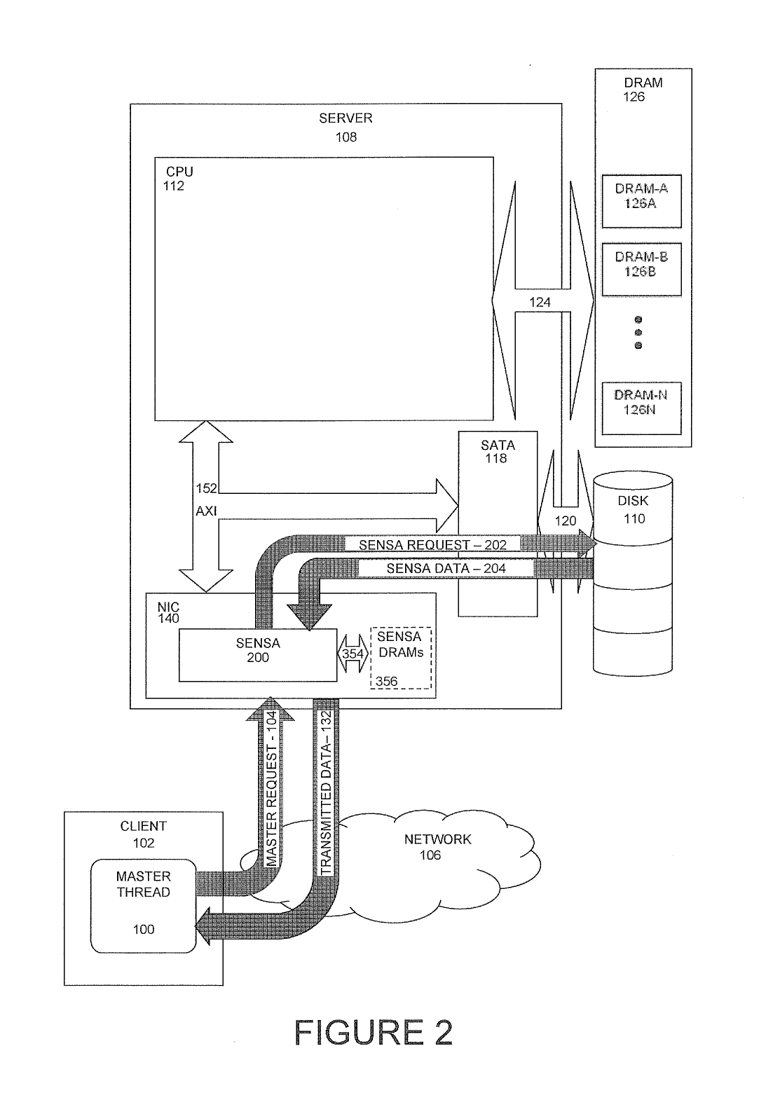

Refer now to FIG. 2, a high-level diagram of an exemplary Software Enabled Network Storage Accelerator (SENSA) implementation. In this exemplary implementation, a SENSA slave storage co-processor module (or simply SENSA co-processor) 200 is shown in a preferred implementation on the NIC 140. Alternatively, the SENSA co-processor 200 can be implemented after the NIC 140, in other words, implemented between the NIC 140, the CPU 112, and the SATA 118. Alternatively, the SENSA co-processor can replace the NIC, obviously requiring additional NIC features to be integrated into the basic SENSA module. SENSA can be implemented as a system on a chip (SoC). SENSA co-processor 200 communicates via SENSA to SENSA DRAMs link 354 to SENSA DRAMs 356.

A significant feature of the SENSA co-processor 200 is implementation of innovative event processing. SENSA can serve as an event processor, where events can come internally from server 108, or externally from network 106 (for example as network packets). In the context of this document, the term “event” generally refers to information received by SENSA, and more specifically to a payload of a received packet, the payload explicitly or implicitly requesting the performance of an associated task. Typically, a task includes an interleaved sequence of routines, including software/firmware routines and hardware engine routines. The event can be at least a portion of the payload, for example part or all of a received packet payload, in the context of this document referred to for simplicity as “payload” or “event”. After receiving an event, SENSA processes/responds to the received event, referred to as SENSA processing the event or referred to as simply SENSA event processing. As will be obvious to one skilled in the art, while the term “event” can refer to a conceptual occurrence (something that happened), the physical instantiation of the event is as a payload of bytes of information representing the occurrence. Event processing should not be confused with conventional packet processing. Accelerated packet processing can include techniques to receive and route network data packets without using a server's CPU. However, the problems and implementations of packet processing are not comparable with the challenges of event processing. Packet processing typically includes operations like forwarding, classification, metering, and statistics gathering of network packets. Packet processing, or packet filtering, includes passing or blocking packets at a network interface based on source addresses, destination addresses, ports, or protocols of the packet being processed. Packet processing includes examining the header of each packet based on a specific set of rules, and based on the specific set of rules, deciding how to process, (handle or filter) the packet. Packet processing options include preventing the packet from passing (called DROP) or allowing the packet to pass (called ACCEPT). In other words, packet processing relates to routing packets based on header information of each packet.

In contrast to packet processing, event processing generally refers to processing the payload, or internal data of the packet. In other words, packet processing deals with external packet information (such as source and destination addresses), while event processing refers to internal packet information. For example, such as notification of a significant occurrence that needs to be handled, requests for data (retrieving), and receiving of data (requests for storing). Event processing includes tracking and analyzing (processing) single pieces or streams of information (data) about things that happen (conceptual events). A conceptual event can be any identifiable occurrence that has significance in the context of a specific application. A conceptual event can be a semantic construct associated with a point in time that may result in an instance of processing of state transitions on the part of the receiver. An event can represent some message, token, count, pattern, value, or marker that can be recognized within an ongoing stream of monitored inputs.

Examples of events include, but are not limited to:
Network traffic:
   Packet received from the network and sent to the host as-is (normal NIC operation).
   Packet is pushed by the host via PCIe and is sent over the network by SENSA (normal NIC operation).
   Protocol signaling packet is received from the network to be terminated in the SENSA stack (for example, TCP ACK).
SENSA internal database (DB) related:
   DB search/update—Memcached lookup/write in the tables kept in DRAMs 356
   Maintenance operation by the host—PCIe transactions.
   Internal maintenance operation like DB scrubbing—initiated by SENSA internal timers.
Disk read/write accesses from remote client to local disk:
   Request—FCoE, iSCSI, or similar operation coming from the network
   Response—read data back arriving from local SAS/SATA over PCIe and is sent to the remote client in form of FCoE, iSCSI or similar packet.
Complex Events:
   Stock exchange market data quote arrives at SENSA in form of UDP packet, then the stock exchange market data is processed by SENSA firmware for relevancy and trading opportunity. If relevant, the stock exchange market data is sent to the host for further processing. This operation includes market data messages filtering, preprocessing, normalizing, etc.
   Stock exchange market data quote can also be fully processed by SENSA resulting in generation of a new event, for example, a new trading order being sent to the exchange.

In general, the master thread 100 requests data (master request 104) via a network 106 from a remote server 108 having associated storage (disk 110). The master request 104 is received at the server 108 by a NIC 140 and intercepted for handling by one or more SENSA co-processor 200 components. In the above described conventional processing, master request 104 is passed from the NIC 140 to the CPU 112. In contrast, in some implementations, the master request 104 is handled by one or more SENSA co-processor 200 components and a SENSA request 202 alternate path used from the SENSA co-processor 200 to the SATA 118 or to a local database kept in SENSA local internal or SENSA DRAMs 356 memory. Use of the SENSA request 202 alternate path avoids the time, processing resources of the CPU 112, and the memory resources of the DRAM 126 of conventional processing of master request 104. After data has been retrieved from disk 110 or the database, the SATA 118 can send the retrieved data as SENSA data 204 to the SENSA co-processor 200. The received SENSA data 204 is then transmitted by the NIC 140 as transmitted data 132 back to the original requesting master thread 100.

For clarity in FIG. 2, conventional connections such as NIC 140 to CPU 112 and CPU 112 to SATA 118 are not shown.

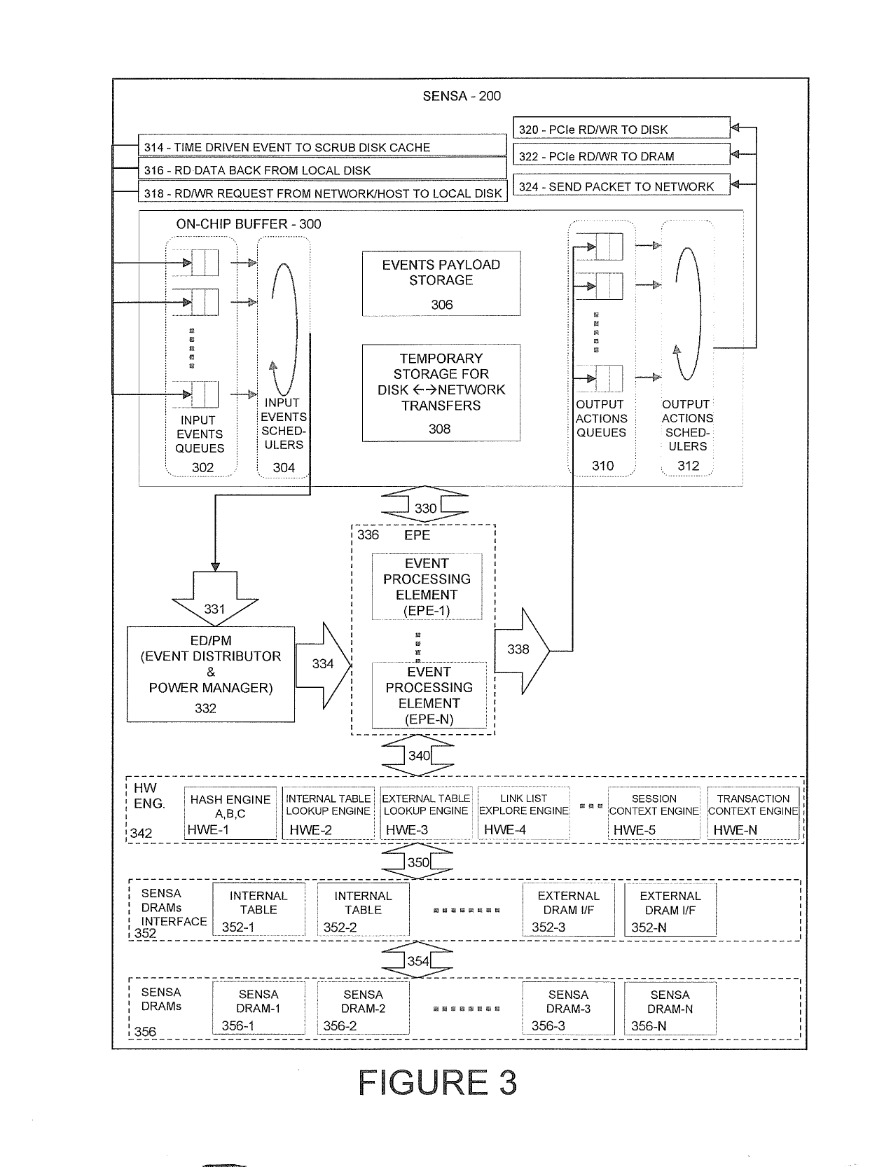

Refer now to FIG. 3, a more detailed diagram of an exemplary Software Enabled Network Storage Accelerator (SENSA) implementation. The SENSA co-processor 200 includes a number of SENSA components that can be implemented individually or in combination.

On-chip buffer 300, also referred to in this document as a “small imbedded buffer”, includes input event queues 302, input events schedulers 304, events payload storage 306, temporary storage 308 for transfers between disk and network, output actions queues 310, and output actions schedulers 312. Inputs to the on-chip buffer include time driven events to scrub disk cache shown as block 314), reading (RD) data back from local disk 110 (shown as block 316), and read/write (RD/WR) requests from network 104/server 108 to local disk (shown as block 318). Outputs from the on-chip buffer 300 include PCIe (PCI Express [peripheral component interconnect express]) read/write (RD/WR) to disk 110 (shown as block 320), PCIe read/write to DRAM 126 (shown as block 322), and sending packets to network/transmitted data 132 (shown as block 324). In the context of this document, input event queues 302 is generally a memory and also referred to as “event queue” and handles event heads, while events payload storage 306 is generally a memory and also referred to as “event buffer” and handles the corresponding event payload tail. In the context of this document, the term “event head” generally refers to the first up to 256 Bytes of an event, and the remaining Bytes of the event (if existing) are referred to as an event tail. Generally, an assumption is that the event head contains sufficient information on which to make a decision how to handle the event. Implementations of input events schedulers 304 include as a single element, multiple elements, and collection of multiple components. Based on this description, one skilled in the art will be able to implement an input events schedulers 304 for a desired application.

As an overview, a received event from input event queues 302 is split in input events schedulers 304 into an event head and event tail. The event head (or simply head) is sent from input events schedulers 304 to event distributor and power manager (ED/PM 332) and then to one of the EPEs in EPE 336. The event tail (or simply tail), if existing, is sent from input events schedulers 304 to events payload storage 306. Typically, the information in the event head is sufficient for processing the received event, otherwise EPE 336 can access via on-chip buffer to EPE link 330 the remaining payload information stored as the event tail in events payload storage 306. After processing by EPE 336, appropriate portions of the event head from EPE 336, new and or additional information from EPE 336, and appropriate portions of the event tail from events payload storage 306 are combined in output actions queues 310. On-chip buffer to EPE link 330 (also referred to as RD/WR access to internal buffer) includes one or more connections between on-chip buffer 300 and EPE 336, typically a plurality of parallel connections or mesh connection. This link allows individual EPEs (EPE-1, EPE-N) in the EPE to read and write data from the various portions of the on-chip buffer 300. For example, reading data from events payload storage 306 and writing data to temporary storage 308.

On-chip buffer to ED/PM (event distributor and power manager) link 331 includes one or more connections from the on-chip buffer 300 to the ED/PM 332, typically a plurality of parallel connections allowing the input events to be communicated to the ED/PM 332.

The event distributor and power manager (ED/PM) 332 module receives events from the input events schedulers 304, and distributes individual events to an individual EPE of EPE 336. The distribution can be a simple round-robin tasks dispatcher, or a more complex algorithm, depending on the specific application.

ED/PM to EPE link 334 includes one or more connections from the ED/PM 332 to EPE 336, typically a plurality of parallel connections allowing the ED/PM to communicate to one or more individual EPE (EPE-1, EPE-N).

In the context of this document, event-processing element (EPE) 336 generally refers to a module system of one or more EPEs. Typically, EPE 336 includes a plurality of EPEs, shown in FIG. 3 as EPE-1, up to and including EPE-N, where “N” is an integer number greater than zero. EPEs are typically symmetrical (identical), and have the same instruction code to execute.

A suggested implementation for EPEs is as an array of identical processors, such as small RISC cores. Preferably, all the EPEs are symmetric and have the same instruction code. Each EPE performs functions including classification of received events, priority decisions, engines arbitration decisions, and main processing functionality Each individual EPE of a plurality of EPEs processes a single task in run-to-completion manner by running associated firmware. Typically, every new task is served by a corresponding individual EPE of EPE 336. A feature of the SENSA implementation is the offloading from the EPEs of the appropriate operations to corresponding hardware engines (HWE). All EPEs can have access to all HWEs.

The EPE implementation features an increased speed of processing, as compared to conventional event handling, so that no unclassified events are waiting to be serviced (by an EPE). Preferably, the number of individual EPEs in EPE 336 is selected (dimensioned) to be large enough to process input events from input events queues 302, in order to maintain input events queues 302 empty. In other words, after an input event is queued in input events queues 302, the queued input event can more to an EPE without waiting for an EPE to become available.

EPEs have direct load/store access to the various queues and buffers in on-chip buffer 300 (via on-chip buffer to EPE link 330) to manage queues (such as input events queues 302) and buffers (such as events payload storage 306). As queues (such as input events queues 302) in on-chip buffer 300 are typically physically implemented in the same shared memory as memories (such as events payload storage 306 and temporary storage 308), the EPEs have load/store access to the queues, in case such access would be needed.

In an exemplary SENSA implementation, EPE 336 is implemented as 48 individual EPEs (EPE-1 to EPE-N, where N=48) RISC cores, such as available from ARM, MIPS, ARC, Tensillica, and Microblaze.

EPE to on-chip buffer link 338 includes one or more connections from the output of EPE 336 to the output actions queues 310 of the on-chip buffer 300.

EPE to HW engine link 340 includes one or more connections between EPE 336 and hardware engine (HWE) 342. The EPE to HW engine link 340 is typically a plurality of parallel connections, and preferably a mesh network of connections. This link can allow communication (including sending/writing and receiving/reading) between individual EPEs (EPE-1, EPE-N) in the EPE 336 and individual hardware engines (HWE-1 to HWE-N) in the HW engine 342.

In the context of this document, hardware engine (HW engine, HWE) 342 generally refers to a system module of one or more hardware engines. Typically, HW engine 342 includes a plurality of hardware engines, shown in FIG. 3 as HWE-1, up to and including HWE-N, where “N” is an integer number greater than zero. The specific number and type of hardware engines is determined by the specific application for which the SENSA, or specifically the HW engine 342, is designed. Examples of hardware engines include, but are not limited to hash engines (HWE-1), internal table lookup engines (HWE-2), external table lookup engines (HWE-3), link list explore engines (HWE-4), session context engines (HWE-5), and transaction context engines (HWE-N). Hardware engines perform tasks offloaded from the EPEs, such as table lookups, HASH calculations, and other computation intensive operations. Additional exemplary implementations of hardware engines include hardware engines for performing hash SHA-1, hash MD-5, hash AES, link list exploration engine, and session context engine. Each HWE implementation can be instantiated multiple times, such as each of the above types of hardware engines being instantiated four times.

The hardware engines do not deal with scheduling or arbitration of events, but only process requests that are arranged in the HWE input queues (not shown in the figures) by the EPEs. HWE input queues are queues in front of each individual HWE, of requests from EPEs to the HWE, to resolve potential issues of instantaneous HWE oversubscription.

Typically, all individual EPEs send requests from an individual EPE to all hardware engines (HWEs) of HWE 342. The sent request is served by an individual HWE, results of the request returned to EPE 336, and then an individual HWE is available to serve another request from any individual EPE.

HW engine to SENSA DRAMs interface (I/F) link 350 includes one or more connections between HW engine 342 and SENSA DRAMs interface 352. The HW engine to SENSA DRAMs I/F link 350 is typically a plurality of parallel connections, and preferably a mesh network of connections. This link can allow communications (including sending/writing and receiving/reading) between individual hardware engines (HWE-1 to HWE-N) in the HW engine 342 and individual DRAM interfaces (352-1 to 352-N). As described in reference to CPU-DRAM connection 124, typically the number of connections 124 to conventional DRAM 126 is limited, as the DRAMs are shared among a number of CPUs and processors. In contrast, SENSA DRAMs I/F link 350 is a dedicated connection between HW engine 342 and SENSA DRAMs interface 352. As such, SENSA DRAMs I/F link 350 can include a larger number of connections between individual 11W engines and individual DRAM interfaces. In an exemplary implementation, four SENSA DRAMs I/F links 350 provide connection to twelve HWEs 342. While conventional CPU to DRAM connections, such as CPU-DRAM connection 124 can provide connectivity similar to mesh networks, conventional designs are limited due to very long latencies (for example due to multi-layering and L1-L3 caches, in comparison to the current SENSA DRAMs I/F link 350.

In the context of this document, SENSA DRAMs interface 352 generally refers to a system module of one or more interface modules and/or memories. Typically, SENSA DRAMs interface 352 includes a plurality of interfaces, shown in FIG. 3 as 352-1, up to and including 352-N, where “N” is an integer number greater than zero. The specific number, configuration, and use of DRAM interfaces are determined by the specific application for which the SENSA, or specifically the SENSA DRAMs interfaces 352, is designed. Examples of configuration and use of SENSA DRAMs interfaces include, but are not limited to storing internal tables (352-1, 352-2) and external DRAM interfaces (I/F) (352-3, 352-N).

SENSA DRAMs interface to SENSA DRAMs link 354 includes one or more connections between SENSA DRAMs interface 352 and SENSA DRAMs 356. The SENSA DRAMs interface to SENSA DRAMs link 354 is typically a plurality of parallel connections, and preferably a mesh network of connections. This link can allow communications (including sending/writing and receiving/reading) between individual DRAM interfaces (352-1 to 352-N) in SENSA DRAMS interface 352 and between individual DRAMs (356-1 to 356-N) (or more generally individual memories). As described in reference to CPU-DRAM connection 124, typically the number of connections 124 to conventional DRAM 126 is limited, as the DRAMs are shared among a number of CPUs and processors. In contrast, SENSA DRAMs interface to SENSA DRAMs link 354 is a dedicated connection between SENSA DRAMs interface 352 and SENSA DRAMs 356. As such, SENSA DRAMs interface to SENSA DRAMs link 354 can include a larger number of connections between individual SENSA DRAMs interfaces 352 and individual SENSA DRAMs 356.

In the context of this document, SENSA DRAMs 356 generally refers to a system module of one or more memories, normally volatile memory, and typically implemented as DRAM (dynamic random access memory) memory. Typically, SENSA DRAMs 356 includes a plurality of DRAMs, shown in FIG. 3 as 356-1, up to and including 356-N, where “N” is an integer number greater than zero. The specific number, configuration, and use of DRAMs is determined by the specific application for which the SENSA, or specifically the SENSA DRAMs 356 is designed. In an exemplary implementation, each individual DRAM (356-1, . . . , 356-N) has single DRAM channel of 72 bits. Examples of configuration and use of SENSA DRAMs include, but are not limited to storage blocks meta-data, storage blocks cache state, and data base (like SAP HANA) components.

In one implementation, SENSA DRAMs 356 can implement the functionality found in conventional DRAM 126. In this implementation, the use of SENSA DRAMs 356 with the innovative SENSA architecture avoids conventional latency using CPU 112 and corresponding latency of the CPU-DRAM connection 124. SENSA DRAMs 356 can implement conventional tables and interfaces similar to DRAM 126, or can implement new and/or custom tables and interfaces to match the SENSA architecture and operation.

In an alternative implementation, the master thread 100 (or client 102) application can also access the slave 114 (or server 108) for a query in the client's local DRAM database (for example, disk cache). This type of the functionality can also be facilitated by SENSA by searching in the local DRAMs (corresponding to SENSA DRAMs 356) for the corresponding data base record. For example, Memcached or Redis applications. Optionally, SENSA can be used to offload the client operation (for example, on client 102) of searching for the appropriate server (for example, server 108) before sending a request (for example, master request 104).

In general, internal communication fabrics (links) such as on-chip buffer to EPE link 330 and EPE to HW engine link 340 can be implemented in a variety of topologies, including but not limited to serial, parallel, plurality of parallel connections, mesh, and ring. Based on this description, one skilled in the art will be able to implement each link using a topology to satisfy the requirements of the specific application.

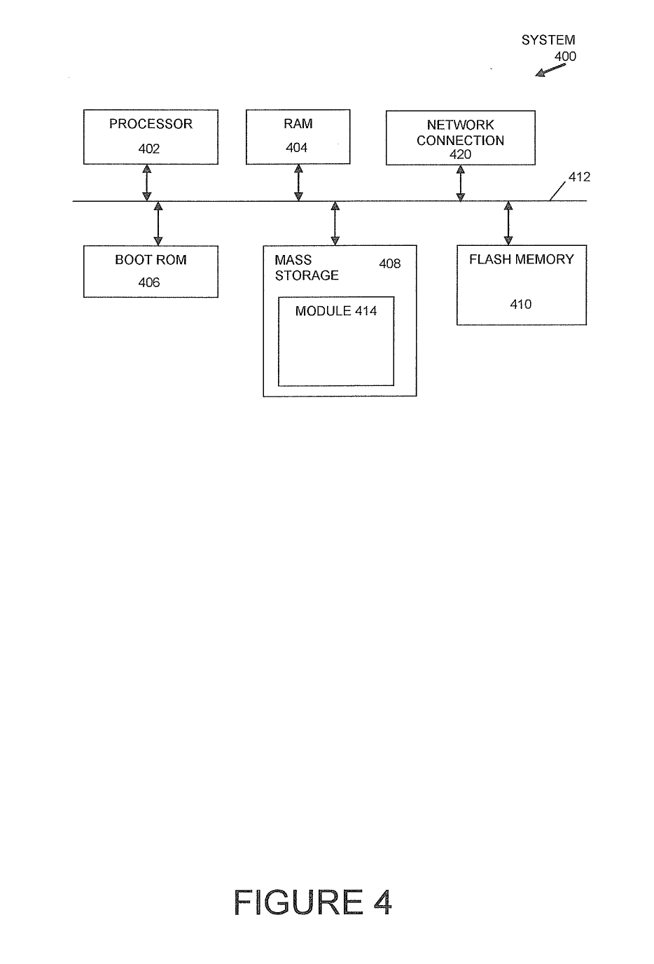

FIG. 4 is a high-level partial block diagram of an exemplary system 400 configured to implement a server 108 of the present invention. System (processing system) 400 includes a processor 402 (one or more) and four exemplary memory devices: a RAM 404, a boot ROM 406, a mass storage device (hard disk) 408, and a flash memory 410, all communicating via a common bus 412. As is known in the art, processing and memory can include any computer readable medium storing software and/or firmware and/or any hardware element(s) including but not limited to field programmable logic array (FHA) element(s), hard-wired logic element(s), field programmable gate array (FPGA) element(s), and application-specific integrated circuit (ASIC) element(s). Any instruction set architecture may be used in processor 402 including but not limited to reduced instruction set computer (RISC) architecture and/or complex instruction set computer (CISC) architecture. A module (processing module) 414 is shown on mass storage 408, but as will be obvious to one skilled in the art, could be located on any of the memory devices.

Mass storage device 408 is a non-limiting example of a computer-readable storage medium bearing computer-readable code for implementing the data retrieval and storage methodology described herein. Other examples of such computer-readable storage media include read-only memories such as CDs bearing such code.

System 400 may have an operating system stored on the memory devices, the ROM may include boot code for the system, and the processor may be configured for executing the boot code to load the operating system to RAM 404, executing the operating system to copy computer-readable code to RAM 404 and execute the code.

Network connection 420 provides communications to and from system 400. Typically, a single network connection provides one or more links, including virtual connections, to other devices on local and/or remote networks. Alternatively, system 400 can include more than one network connection (not shown), each network connection providing one or more links to other devices and/or networks.

System 400 can be implemented as a server or client connected through a network to a client or server, respectively. In an exemplary implementation, system 400 is configured to implement a server 108 of the present invention. In this implementation, processor 402 can function as CPU 112, RAM 404 can function as DRAM 126 or SENSA DRAMs 356, network connection 420 can support master request 104 and transmitted data 132, mass storage 408 can function as disk 110, and common bus 412 can be implemented as internal bus 152. In a less preferred implementation, EPE 336 can be implemented as a computer program (software, computer-readable code). The computer program includes program code stored on a computer-readable storage medium such as mass storage 408 (disk 110).

### DETAILED DESCRIPTION

### First Embodiment

An innovative SENSA component of the general SENSA system is an apparatus and method for hardware (HW) real time operating system (RTOS) optimization for network storage stack applications. In general, this first embodiment provides an innovative implementation for event processing using a multi-core array with coprocessors. The current embodiment is particularly suited for processing complex L4-L7 networking protocols and storage virtualization applications.

A system for hardware RTOS optimization for network storage stack applications includes an array of at least one event processing element (EPE). Each EPE in the array is configured for receiving events. Each of the events has a task corresponding to the event. Each EPE is configured for processing the task in run-to-completion manner by operating on a first portion of the task and offloading a second portion of the task.

In conventional cases of complex system on a chip (SoC) implementations, there are network and storage related tasks that require deterministic performance and hardware resources access. Characteristics of these tasks include:
High rate of events such as:
event per packet coming to/from the network,
event per disk access from external application in the distributed storage systems,
timing driven event, generated by internal timers;
Multiple table lookups involved in the processing thread;
Limited SW processing required for the events treatment; and
High volatility of functionality—protocols and algorithms are constantly emerging.

Typically, network and storage related tasks are addressed by conventional solutions such as:
Software (SW) RTOS running on the main CPU complex—generally using different scheduling algorithms in software to provide deterministic latency (priority preemption, time division, and other algorithms),
Multi-threading—generally an approach where an event is passed from a first execution node performing a first type of processing to subsequent execution nodes performing different subsequent processing,
Hardware co-processors, such as security engines, and
Network offload engines like remote DMA (direct memory access) (RDMA), RDMA over converged Ethernet (RoCE), TCP offload engine (TOE), etc., and
Hardware schedulers—generally a hardware scheduler generating exceptions and interrupts to CPUs in order to have the CPU process events.

The above-described conventional solutions provide lower performance than required to meet the demands of current applications, and/or are limited in flexibility to adapt to the changing requirements of current and future applications. There is therefore a need to provide an apparatus and method for hardware RTOS optimization for network storage stack applications.

An embodiment for providing hardware RTOS optimization for network storage stack applications is an innovative event processing system and method using a multi-core array with coprocessors, as described above in reference to FIG. 3, event processing elements (EPEs 336) and further described here.

In general, this embodiment of a component of the general SENSA system includes an array of event processing elements (EPEs) EPE 336. Each EPE in the array is configured for receiving events. Each of the events is sequentially received and has a task corresponding to the received event.

Preferably, each EPE in the array is identical (symmetrical) and configured with identical firmware instruction code. The array includes at least one EPE, normally at least two EPEs, and typically a multitude of EPEs.

EPE 336 can receive events from conventional sources such as the CPU 112, conventional slave threads (such as slave thread 114), master threads (such as master thread 100), or NIC 140. Optionally and preferably, EPE 336 can be implemented with other SENSA components. For example, when EPE 336 is combined with a SENSA on-chip buffer 300, events can be received from an event distributor 332 based on an input events scheduler 304. The event distributor 332 can be configured with a round robin tasks dispatcher algorithm to distribute events to each EPE in the array of EPEs 336. In a case where EPE 336 is implemented with the on-chip buffer 300, each EPE can have direct load and store access to memories and queues in an on-chip buffer 300, including, but not limited to an events payload storage memory 306 and a temporary storage 308 configured for transfers between disk and network. An implementation technique for optimizing performance of the EPE 336 is to construct the EPE 336 such that the array of EPEs contains a number of EPEs greater than a maximum number of unclassified events waiting to be serviced in an input events queues 302.

Each task (received event) received by an individual EPE of EPE 336 is preferably processed in run-to-completion manner by operating on a first portion of the task and offloading a second portion of the task. Alternatively, the individual EPE can process the entire received task, in other words, not offload a portion of the received task. Typically, an event associated task includes a logical portion and a calculation or I/O intensive portion. Logical portions include extracting fields from an event payload and making processing flow decisions. Logical portions can efficiently be handled by firmware routines in the EPE 336. Calculation or I/O intensive portions include performing lookups in large tables and HASH computations. Calculation or I/O intensive portions can efficiently be handled by hardware engine routines in HWE 342.

Thus, typically, a task includes an interleaved sequence of firmware routines and hardware engine routines. Firmware routines are generally referred to in the context of this document as “first portions”. Optionally, first portions can also include software routines. Hardware engine routines are generally referred to in the context of this document as “second portions”. Tasks normally have at least one firmware routine that is handled by EPE 336. A task can have zero or more hardware engine routines that are offloaded from EPE 336 and handled by HWE 342.

A significant feature of the current embodiment is the architecture and method of the EPEs sharing instructions (firmware routines and hardware engine routines), sharing memories, and providing statefull processing.

Each EPE includes instruction code to execute on that EPE. Preferably the instruction code is firmware and identical on all EPEs. The instruction code is configured to implement operating on at least a first portion of the task. The first portion of the task includes functions including, but not limited to:
Classification of received events. Classification in an EPE generally refers to discovering a type of the event. In other words, analyzing at least a portion of the payload of a received packet header and determining what is an associated task.
Deciding on a priority for each received event.
Deciding how to process the classified event.
Arbitrating decisions regarding hardware processing engines (HWEs).
Main processing functionality—firmware routines for logical portion processing of a task.

Normally a received task includes a second portion that is computationally intensive. While this second portion can be processed by the receiving EPE, preferably processing of this second computationally intensive portion is offloaded to a hardware engine (HWE) module.

The EPE 336 can be connected via a network, such as EPE to HW engine link 340 to a hardware engine (HWE) module 342, as described above with reference to HWE 342 and related components.

### Second Embodiment

An innovative SENSA component of the general SENSA system is an apparatus and method of bypassing server central processing unit (CPU) by redirecting data transactions between network and disk. In general, this sixth embodiment provides an innovative implementation for intercepting network to disk data traffic and performing transactions on this data using internal logic rather than a CPU, providing transparent functionality with improved performance as compared to conventional solutions. The current embodiment is particularly useful in sending and receiving data blocks between network connections and disk storage, such as in distributed storage servers.

In general, a network to disk DMA (NDDMA) module is configured as part of a server. The NDDMA includes a network sub-module configured to receive data packets and determine if received data packets are regular data packets or storage data packets. A disk storage sub-module is configured to store storage data packets in disk storage. A transfer sub-module is configured to transfer storage data packets to the disk storage sub-module and initiate transfer of regular data packets to a component of the system other than the disk storage sub-module.

In conventional servers, such as systems on a chip (SoCs), data is transferred among internal components under direction of a CPU, thus implementing a CPU-centric technique for data transfer. For example, data travelling between a first component and a second component, such as from an Ethernet port to disk is transferred via the CPU from the first component to the second component. This conventional technique of data passing data through the CPU, and/or transferring under control of the CPU results in undesirable characteristics including interrupting the CPU by external events just to receive/extract a block of data from the network/disk and send the data to the disk/network. In conventional systems, the worlds of network and disk co-existed in servers, and communicate to each other via the CPU only. This was acceptable, since the disk data was always destined to the local CPU, so the CPU involvement in each disk transaction was natural. However, current network-disk access includes distributed storage, introducing new functionality when the disk belonging to the server (for example, server A) is accessed by another server (for example server B) via the network.

Conventional CPU-centric techniques for data transfer include:

Memory to memory DMAs (direct memory addressing) use existing reads and writes from memory.

Disk to disk DMAs use disk transactions performed by disk controllers.

Memory to network to memory DMAs perform transactions by RDMA (remote DMA) functionality, typically implemented over Infiniband, TCP (iWARP) or converged Ethernet (RoCE—RDMA over Converged Ethernet).

The above-described conventional CPU-centric techniques fail to provide sufficient support for bridging memory, disk, and network.

There is therefore a need for a system and method of implementing a network-storage data path using less CPU resources, preferably no CPU resources, and having greater bandwidth than conventional techniques.

An embodiment of a system and method of implementing a network-storage data path includes a network to disk DMA (NDDMA) module (or referred to in the context of this document simply as “NDDMA”). In general, this embodiment of a component of the general SENSA system includes an NDDMA module implemented in SENSA 200. For clarity in describing this embodiment, NDDMA will be used in the context of a SoC (acting as a server). However, based on this description one skilled in the art will be able to implement the NDDMA in other locations and configurations. For clarity in this description the term “disk storage” or simply “disk” or “storage” will be used to refer to a typical case of hard disk storage, however this term should not be interpreted as limiting, and one skilled in the art will realize that the term “disk storage” can also include modern large volatile or non-volatile memories and other data storage components and implementations.

The NDDMA is generally a dedicated module dealing with network and disk traffic, a DMA-like machine transferring data from/to network to/from disk. The NDDMA off-loads work from CPU(s), providing data transfer without the need for CPU processing. The NDDMA typically includes three sub-modules: a network sub-module, a disk storage sub-module, and a transfer sub-module. The network sub-module includes logic that parses a received data packet and maintains protocols. The disk storage sub-module includes logic to communicate with disk controllers, for example SATA/SAS. The transfer sub-module includes logic to move data between disk and network (or NIC 140), using internal temporary buffers if needed. As will be obvious to one skilled in the art, the NDDMA sub-modules can be co-located, or distributed (for example to be closer to the respective areas of operation) with appropriate communications between the modules.

In a typical implementation of NDDMA, requests from clients (for example master request 104 from client 102) are intercepted by the NDDMA, for example by the network sub-module. The network sub-module parses the received data packet to determine if the data packet is “regular” data that needs to go to the CPU or if the data packet is “storage” data and needs to be stored to disk. Regular data is not off-loaded, but transferred to the CPU, for example via AXI 152 to CPU 112. Storage data is handled by the transfer sub-module that moves the received data to the disk storage sub-module, for example using SENSA request 202 via SATA 118 to disk 110. If the regular data or storage data needs to be buffered, internal temporary buffers can be used, such as SENSA DRAMs 356 or preferably temporary storage 308 for transfers between disk and network, in order to avoid use of CPU 112 and DRAM 126. The disk storage sub-module handles storing and retrieving data from disk. Alternatively, storage data can be transferred to other SENSA components for handling, for example to ED/PM 332 for processing by EPE 336.

In an exemplary embodiment, the NDDMA module is implemented by a software enabled network storage accelerator (SENSA) module 200. Alternatively, the NDDMA module can be implemented by a hardware engine (HWE) 342. The NDDMA sub-modules can be implemented by various SENSA components, depending on the specific implementation requirements. For example, the network sub-module can be implemented by the input events schedulers 304, the disk storage sub-module can be implemented by the output actions queues 310, and the transfer sub-module can be implemented by the event distributor and power manager (ED/PM) 332.

The NDDMA can be implemented by SENSA 200 or in SENSA 200. Storage data can be brought into the NDDMA as read/write (RD/WR) requests from network to local disk (shown as block 318). The NDDMA can send data as read/write (RD/WR) to disk (shown as block 320). Transfer sub-module can be implemented as ED/PM 332. Optionally or additionally, NDDMA can be implemented as a dedicated hardware engine in HWE 342. If the NDDMA needs to temporarily store data, SENSA DRAMs 356 are preferably used in order to avoid use of CPU 112 and DRAM 126.

### Third Embodiment

In an alternative embodiment, EPEs 336 are configured to process only the task portions for which CPU 112 is ill-suited, i.e. the data access portions of the tasks. In support of this processing, the address tables of disk 110 are stored in DRAMs 356 in addition to, or in place of, being stored in DRAMs 126. The remainders of the tasks are performed by CPU 112 in the conventional manner.

If master request 104, in the form of one or more network packets, includes a request to read data from disk 110 or to write data to disk 110, SENSA 200 intercepts the packets as described above. Input events scheduler 304 inspects the packets. A packet that includes a request to read data from disk 110 or to write data to disk 110 is scheduled for handling by one of EPEs 336. All other packets are forwarded to CPU 112 via output action queues 310 and output action scheduler 312. The EPE 336 that is selected to handle the read request uses the appropriate HWEs 342 to hash the logical addresses of the requested data and to look up the corresponding physical addresses in one or more address tables in DRAMs 356. The EPE 336 then duplicates the packet that includes the read request, but with the physical addresses in place of the logical addresses, along with a flag that indicates to CPU 112 that the addresses are physical addresses rather than logical addresses. The EPE 336 sends the packet to output action queues 310, from where output action scheduler 312 forwards the packet to CPU 112. Upon receiving the packet, CPU 112 recognizes the addresses as physical addresses and sends the addresses to SATA 118 in the conventional manner. If data are to be read from disk 110, SATA 118 reads the data and sends the data to CPU 112. If data are to be written to disk 110, the physical addresses are accompanied by the data and SATA 118 writes the data to the requested blocks in disk 110.

In support of writing data to disk 110, the EPE 336 that receives the packet also uses HWE-1 to hash each block of the data in the payload and appends the hashes to the payload. CPU 112 compares the hashes to the corresponding hashes that are stored in disk 110 along with the targeted blocks of disk 110, and skips writing to blocks whose hashes are identical to the hashes of the data that are to be written to the blocks. In this manner, re-writing data that already are present on disk 110 is avoided.

### Fourth Embodiment

An innovative SENSA component of the general SENSA system is an apparatus and method for saving static and dynamic power in systems on a chip (SoCs) with an array of multiple RISC cores. In general, this fourth embodiment provides an innovative implementation for adjusting power consumption, in particular saving power in event processing systems having an array of processing elements. The current embodiment is particularly suited for saving power during standby (static) and active (dynamic) use of an array of event processing elements (such as EPE 336) and associated hardware engines (such as hardware engines 342) and volatile memory (such as SENSA DRAMs 356).

The current embodiment features an innovative combination of architecture and algorithm, facilitating turning on and off (putting into active and standby modes) elements of the SENSA system with a higher granularity as compared to conventional implementations. An event distributor/power manager (ED/PM 332) matches input queues queue occupancy to how many elements, such as EPEs in EPE 336, need to be active to continuously process incoming events without delaying event processing. Both instantaneous and average power can be controlled, in particular reduced to lower levels than in conventional systems while maintaining continuous processing of a varying level (number) of received events. This results in the power consumption being optimally tuned to the instantaneous workload. As compared to conventional solutions, the current SENSA component implementation is a complex system approach taking into considerations multiple factors, and the algorithm can be implemented autonomously for more dynamic system re-configuration (than conventional solutions).

According to the teachings of the present embodiment there is provided a system including: an input queue having an instantaneous queue length (IQL) and an average queue length (AQL), the input queue configured for storing incoming events and transmitting the stored events to a tasks distributor configured to receive events from the input queue and distribute events to an array of processing elements configured to receive events from the tasks distributor; having an active portion of zero or more elements in an active-state; and having a sleeping portion of zero or more elements in a sleeping-state, wherein the tasks distributor is additionally configured for: adjusting a size of the active portion based on the AQL.

In conventional complex systems on a chip (SoCs) implementations, such as SoCs used for Wi-Fi access points, mobile base station controllers, and similar SoCs there is a tradeoff between using CPU (central processing unit) centric and NPU (Network Processing Unit) centric chip solutions:

CPU centric based SoCs typically allow easy programming models as compared to NPUs, but suffer from performance and power issues.

NPUs provide deterministic performance, but are limited in features and difficult to program as compared to CPUs.

There are architectures that attempt to combine advantages of both CPU and NPU centric approaches, such as multi-core NPU-like solutions. These multi-core NPU-like solutions are dimensioned for maximal event rate to guarantee performance of the multiple NPU core array at peak loads. This performance is at the expense of power consumption of the multiple NPU core array.

There is therefore a need for a system and method for saving static and dynamic power in systems on a chip (SoCs) with an array of multiple RISC cores.

An embodiment of a power management method for saving static and dynamic power in systems on a chip (SoCs) with an array of multiple RISC cores includes dynamic re-configuration of SoCs in order to adjust the instantaneous power consumption of the SoC to current system load.

In the context of this description, the term “active portion” generally refers to a portion of elements that is active and ready to receive and process events. In other words, the set of individual elements that are receiving power and clock, awake, and ready to perform designated functions. The size, or amount, of the active portion corresponds to how many elements are active. Elements in the active portion are referred to as being in an active-state.

In the context of this description, the term “sleeping portion” generally refers to a portion of the elements that is inactive and unable to receive and process events. In other words, the set of individual elements that are not receiving power and/or clock, in a power-down mode, and unable to perform designated functions. The size, or amount, of the sleeping portion corresponds to how many elements are sleeping. Elements in the sleeping portion are referred to as being in a sleep-state.

Techniques for configuring components as active or sleeping are known in the art, for example, using clock and power gating to the components. In SENSA, a preferred implementation is to control the gating of clock and power to individual EPE components in the EPE 336 and optionally individual hardware engines in HWE 342.

For the current embodiment, active portions and sleeping portions are described for EPE 336 and HWE 342. Based on this description, one skilled in the art will be able to implement additional and alternative power saving for other components of the system.

In general, this embodiment of a component of the general SENSA system includes an input buffer, an elastic buffer, a tasks distributor, an array of processing elements, and optionally network port bandwidth meters.

The input buffer, such as input events queue 302 has an instantaneous queue length and an average queue length. The input events queue is configured for receiving, storing, and transmitting events. In other words, maintaining a queue of incoming, or received events, as pending events to be processed. The input events queue 302 has a depth that is driven by factors including: length of worst-case input events burst and length of power up sequence. Depth can be calculated as:

Depth=max((MaxInBW−MinProcBW)*BurstLen,MaxInBW*PowerUpSeqLen*MaxSleepingRatio+DelayConst)

where:
MaxInBW—maximal possible rate of input events
MinProcBW—minimal processing rate of events
BurstLen—maximal length of input events burst
PowerUpSeqLen—time required to power up sleeping EPEs
MaxSleepingRatio—maximal percentage of sleeping EPEs
DelayConst—safe margin of the implementation delays.

The elastic buffer can be implemented as a combination of the above-described input events queue 302 and input events scheduler 304. The elastic buffer is configured to receive events from the input buffer and transmit events to the ED/PM.

The tasks, or packet, distributor, such as event distributor and power manager (ED/PM) 332 is configured to receive events from the elastic buffer, such as via input events scheduler 304. The ED/PM is configured to distribute events to the EPE 336. The distribution is based on at least the average queue length. Distribution is to an active portion of the EPE 336. The ED/PM is also configured to vary how many individual EPEs are in an active portion of EPE 336 and how many individual EPEs are in a sleeping portion of EPE 336. Similarly, ED/PM can also be configured to vary how many individual hardware engines are in an active portion of HWE 342 and how many individual hardware engines are in a sleeping portion of HWE 342. Control of active/sleeping portions is described further below.

The array of processing elements, such as EPE 336, has an instantaneous array utilization and average array utilization. The EPE 336 is configured to receive events from the ED/PM and process events.

Optionally, the embodiment can also include one or more network port bandwidth meters configured to monitor one or more associated network ports for received events. Various implementations are possible for the network port bandwidth meters, for example, dedicated logic (not shown in the figures) associated with the RD/WR requests from network/host to local disk 318 or as an entry in an internal table (such as 352-1) which is updated by the EPE 336.

A power management method of the current embodiment includes tracking amount of incoming events, event queuing, and using feedback to match active resources to the amount of incoming events. In other words, to match size of the active portion to current workload. An exemplary implementation is now described using negative feedback for matching a size of an active portion to the instantaneous demand for processing of incoming events. Preferably, the current method is implemented in the ED/PM 332, having access to the incoming events and control to turn on/off (make active/put to sleep) individual EPEs in EPE 336 (and HWE 342, etc.). The ED/PM 332 decides to turn off the power of certain EPEs according to an algorithm as follows.

Since typically all the EPEs are symmetrical and have the same instruction code to execute, the number of active EPEs depends on the average queue length (AQL) of all incoming events queued and waiting to be processed. Typically, a single event is handled by an individual EPE of the EPEs 336, so the AQL level directly dictates the number of EPEs that need to be awake (in the active portion). In other words, AQL levels directly dictate the number of EPEs to be waked up (made active) or are not needed and can be put to sleep (made inactive). The AQL can be derived from an instantaneous queue length (IQL). IQL can be measured or received, periodically or as needed, from the input buffer and/or elastic buffer (input events queue 302 and/or input events scheduler 304.

The IQL can be used to calculate an average queue length as:

AQL=(1−Wq)*AQL+Wq*IQL

where:
Wq is a “relaxing factor” preventing frequent turning on (activating) and turning off (putting to sleep) caused by spikes in events traffic. Wq is typically a very small number <0.01. The exact value of Wq can be adjusted based on the specifics of an implementation.

As described above, based on the AQL the ED/PM 332 can activate or put to sleep individual EPEs to match the size of the active portion to the amount of incoming events. In addition to using the AQL, the ED/PM 332 can adjust the active portion and sleeping portion based on other inputs and/or system metrics such as anticipating the workload, statistics of pre-classified events, and network port bandwidth monitoring. Other system metrics can also be used to enhance the basic control algorithm. For example, using the EPE's instantaneous array utilization and average array utilization as feedback to determine if an adjustment of the active portion is necessary, will be necessary, was sufficient, or to alter algorithm parameters for future adjustments to better match pending task load to the size of the needed active portion.

Redundant elements (such as individual EPEs) can be used to increase processing throughput of the system. For example, when the ED/PM 332 anticipates the workload dropping, some EPEs can be powered-off according to the AQL levels. Similarly and in opposite function, if the ED/PM 332 anticipates the workload increasing, additional EPEs can be powered-on according to the AQL levels.

Optionally, when events enter the input events schedulers 304, the events can be pre-classified to determine which hardware engines will be required for processing the pending events. If the input queue contains events that do not need to consume (use) certain hardware engines, then these hardware engines can be put to sleep, thereby saving additional power in HWE 342. This option saves consuming power for pending services. Typically, pre-classification information (such as statistics of pre-classified events) is sent from the input events schedulers 304 to the ED/PM 332, and then the ED/PM 332 coordinates adjusting active and sleeping portions of EPE 336 and HWE 342.

Additionally and optionally, information from network port bandwidth monitoring can be used by the ED/PM 332 to adjust the active portion and sleeping portion, similar to the anticipation and pre-classification described above.

The current embodiment is particularly suited for complex system on a chip (SoC) event processing implementations on servers, network processors (network processing units, NPUs), and micro-controllers, in particular tasks that require deterministic performance and hardware resources access.

### Fifth Embodiment

An innovative SENSA component of the general SENSA system is an apparatus and method of bypassing server DRAM by redirecting internal data transactions to an embedded buffer. In general, this fifth embodiment provides an innovative implementation for intermediate storage for internal transactions, providing transparent functionality with improved performance as compared to conventional solutions. Transaction throughput is improved at least in part by avoiding using conventional DRAM, thus eliminating conventional bottlenecks in DRAM intermediate storage. The current embodiment is particularly useful in sending and receiving data blocks between disk storage and network connections.

In general, an embedded buffer is configured as part of a server. The embedded buffer includes a temporary storage buffer configured for intermediate storage of transactions; a buffer management module configured for making decisions about subsequent read and write operations to the temporary storage buffer; an arbitration module configured for arbitrating transactions between components of the server; and signaling logic providing a handshake mechanism between elements of the embedded buffer and the components of the server.

In conventional servers, such as systems on a chip (SoCs), data is transferred among internal components under direction of a CPU using main DRAM, thus implementing a CPU-centric technique for data transfer. For example, data travelling between a first component and a second component, such as from one Ethernet port to another Ethernet port, between an Ethernet port and SATA, or between an Ethernet port and a WIFI port is transferred (copied) from the first component to DRAM for intermediate storage and then from DRAM to the second component. This conventional technique of passing data through DRAM results in undesirable characteristics including:
Higher power consumption of the server for the entire process due to high power consumption of DRAM I/O transactions, as compared to the power required for only the component functions.
Degradation of DRAM bandwidth.
Increased latency of end-to-end transactions due to limitations of DRAM speeds.

Conventional techniques for transferring data among internal components, such as DMA and network management systems, fail to address the above problems.

There is therefore a need for a system and method of bypassing the server DRAM for internal data transactions.

An embodiment of a system and method of transaction management for bypassing the server DRAM includes redirecting internal data transactions to an embedded buffer. In general, this embodiment of a component of the general SENSA system includes an embedded buffer, such as on-chip buffer 300. For clarity in describing this embodiment on-chip buffer 300 will be used in the context of a SoC (acting as a server). However, based on this description one skilled in the art will be able to implement other embedded buffers with the innovative features of the current embodiment.

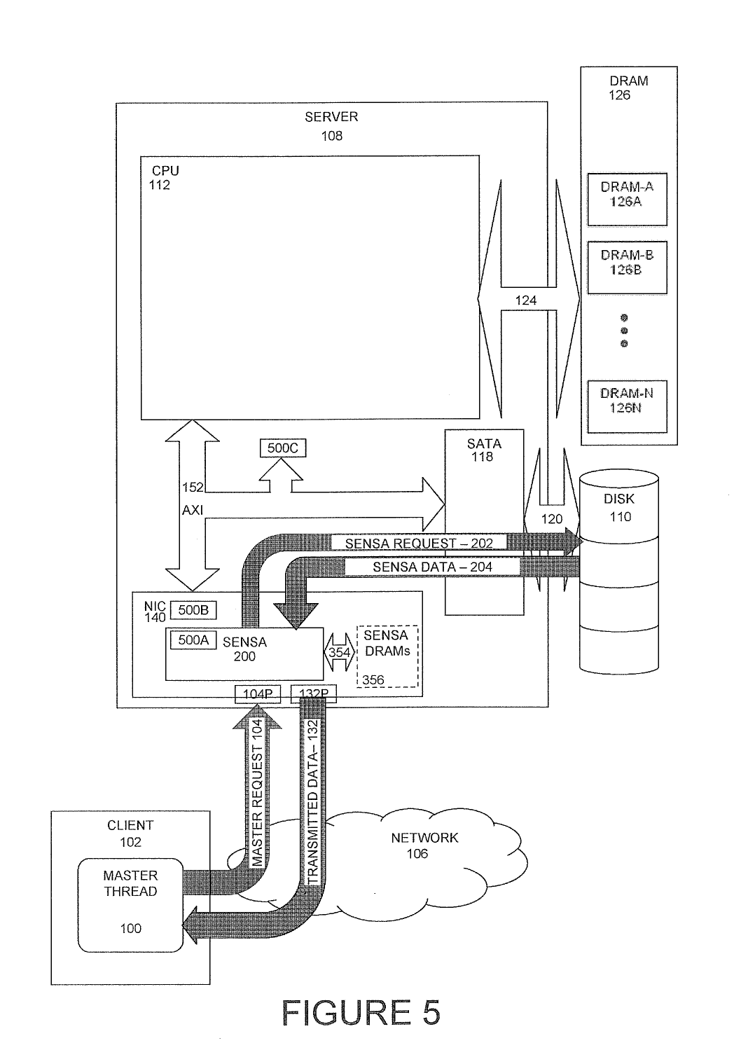

Referring to FIG. 5, the high-level SENSA diagram of FIG. 2 additionally shows implementations of an embedded buffer of the current embodiment. The embedded buffer is preferably implemented in the SENSA 200 as on-chip buffer 300 shown in the current figure as 500A. On-chip buffer 300 can also be implemented on the NIC 140 (shown as 500B), or closer to the CPU 112 (shown as 500C). When implemented as 500C, the on-chip buffer 300 can be used directly by CPU 112.

The current figure also explicitly shows an exemplary input port 104P (implied by master request 104), and an exemplary output port 132P (implied by transmitted data 132). One skilled in the art will realize that input port 104P and output port 132P are non-limiting examples, and include other input and output ports for Ethernet, Wifi, attached storage, etc.

The embedded buffer (300, 500A, 500B, or 500C) can include several elements including a temporary storage buffer. The temporary storage buffer can be implemented as at least two sub-buffers, preferably as a multitude of sub-buffers, the cumulative size of the sub-buffers sufficient for satisfying the buffering requirements of the embedded buffer. This implementation allows one or more of the sub-buffers to be powered-off. For example, each of the sub-buffers, or one or more sub-sets of sub-buffers can be under control of an event distributor/power manager, such as ED/PM 332. The ED/PM can be configured to control an active portion and sleeping portion of sub-buffers based on a current workload.

In the context of this embodiment, the term “SoC” includes, but is not limited to the functionality of server 108 (with components including CPU 112, DRAM 126, SATA 118, input port 104P, output port 132P, and SENSA 200).

In the context of this embodiment, the term “transaction” includes, but is not limited to requesting, reading, providing, writing, and transferring data between components of a SoC, in particularly sending and receiving data blocks between disk storage and network connections. For example, data received on an Ethernet port being stored on disk, data from disk being transferred for sending from a WIFI port, data received on a WIFI port being sent from an Ethernet port, and data received in a master request 104 being used during processing an associated event to access data on disk 110 and return the data via transmitted data 132.

Features of the embedded buffer include:
A temporary storage buffer smaller in size, as compared to conventional buffers. Conventional buffers typically use on the order of gigabytes (GBytes) of main DRAM for storing transaction data. In contrast, a feature of the current embodiment is using a small amount of data, which in this case is on the order of a few kilobytes (Kbytes) or a few multiples of MTU (maximum transmission unit). As the embedded buffer can control both disk and network operations, the embedded buffer can buffer a small, just sufficient, amount of data, as compared to conventional solutions.
Serves as intermediate storage for server internal transactions.
Preferably memory mapped to be visible (accessible) by server components (such as CPU 112, SATA 118, DMA, and network ports).
Buffer management logic module making smart decisions about subsequent read and write operations. Buffer management logic assists with queuing and pre-fetching transactions taking into account the DRAM, disk, and network rates.
An arbitration module arbitrating transactions between the server components (such as CPU 112, SATA 118, DMA, and network ports). The arbitration module is suited for a variety of applications, such as data base acceleration, disk caching, and event stream processing applications. Transaction events can come internally (for example from server 108), or externally (for example from network 106, such as network packets). The arbitration module is particularly significant for improving performance of real time and latency sensitive applications.
Signaling logic provides a handshake mechanism with components and monitors transactions to avoid overrun and underrun conditions. Signaling logic assists with PCIe and Ethernet flow control functionality.

The above-listed features of the embedded buffer facilitate transparent functionality of the embedded buffer and improved performance and power characteristics, as compared to conventional solutions.

Referring again to FIG. 3, a non-limiting implementation of the embedded buffer as on-chip buffer 300 is now described. As described above, the on-chip buffer 300 is configured as part of a server. In this case, the server is server 108 including components such as CPU 112, SATA 118, NIC 140, DMA, and network ports such as input port 104P and output port 132P. On-chip buffer 300 includes a temporary storage buffer, such as temporary storage 308, configured for intermediate storage of transactions. On-chip buffer 300 includes a buffer management module, such as input events schedulers 304, configured for making decisions about subsequent read and write operations to the temporary storage buffer. On-chip buffer 300 includes an arbitration module, such as event distributor and power manager (ED/PM 332), configured for arbitrating transactions between components of the server.

On-chip buffer 300 includes signaling logic providing a handshake mechanism between elements of the embedded buffer and components of the server. Signaling logic includes, but is not limited to signals between:

time driven events to scrub disk cache 314 and input event queues 302,

reading (RD) data back from local disk 316 to input event queues 302,

read/write (RD/WR) requests from network/server to local disk 318 to input event queues 302,

input events schedulers 304 to ED/PM link 331 (ED/PM 332),

output actions schedulers 312 to PCIe (PCIe read/write to disk 320,

output actions schedulers 312 to PCIe read/write to DRAM 322, and

output actions schedulers 312 to sending packets to network/transmitted data 324.

Depending on whether EPE 336 is implemented, signaling logic can include ED/PM to EPE link 334, on-chip buffer to EPE link 330, EPE to HW engine link 340, and EPE to on-chip buffer link 338, or alternatively direct connection from ED/PM 332 to temporary storage 308, etc. Depending on where the embedded buffer is implemented (500A, 500B, 500C) additional connections (not shown) can connect elements of on-chip buffer 300 to components of the server.

Monitoring and control of signaling logic can be implemented by the buffer management module and/or the arbitration module. The module implementing signaling logic control (buffer management module and/or the arbitration module) can be configured to use the signaling logic for control for avoiding overrun conditions in the temporary storage buffer; avoiding underrun conditions in the temporary storage buffer; controlling flow of PCIe; and controlling flow of Ethernet.

Preferably, the embedded buffer, on-chip buffer 300 is memory mapped to be accessible by the components of the server. Transactions can come from sources internal or external to the server, and can be events, as described above.

The buffer management module, input events schedulers 304, can be further configured for assisting with queuing and pre-fetching transactions based on operational rates of DRAM, disk, and/or network. Additionally or alternatively, the buffer management module and/or the arbitration module can be configured to use the signaling logic for control including: avoiding overrun conditions in the temporary storage buffer; avoiding underrun conditions in the temporary storage buffer; controlling flow of PCIe; and controlling flow of Ethernet.

The current embodiment is particularly suited for complex system on a chip (SoC) event processing implementations on servers, network processors (network processing units, NPUs), and micro-controllers.

### Sixth Embodiment

That every EPE processes the tasks every EPE receives in a run-to-completion manner renders CPU 112 and its DRAM 126 redundant. All requests from client 102 can be treated as events to be handled by a SENSA co-processor 200. Whatever temporary storage CPU 112 uses DRAM 126 for is done using SENSA DRAMs 356. In particular, the relevant address tables for disk 110 are stored in SENSA DRAMs 356.

More generally, a server that services events received from a client 102 via network 106 includes NIC 140 and a co-processor that services the events. The co-processor may be part of NIC 140 as illustrated in FIG. 2 or may be separate from NIC 140. The most preferred embodiment of such a co-processor is SENSA 200 as described above, but the scope of this aspect of the present invention includes other preferred embodiments. In particular, the co-processor may include only one processor, which may or may not be an EPE as described above. If the co-processor includes more than one such processor, these processors need not be identical. The only basic requirement is that the co-processor also include hardware engine 342, and that the processor(s) offload some of their processing, as required to the specialized hardware engines of hardware engine 342.

Under this aspect of the present invention, CPU 112 and DRAM 126 are optional: CPU 112 and DRAM 126 may or may not be present in the server. FIG. 2 illustrates a server according to this aspect of the present invention in which CPU 112 and DRAM 126 are retained.

Note that a variety of implementations for modules and processing are possible, depending on the application. Modules are preferably implemented in software, but can also be implemented in hardware and firmware, on a single processor or distributed processors, at one or more locations. The above-described module functions can be combined and implemented as fewer modules or separated into sub-functions and implemented as a larger number of modules. Based on the above description, one skilled in the art will be able to design an implementation for a specific application.

The use of simplified calculations to assist in the description of this embodiment does not detract from the utility and basic advantages of the invention.

To the extent that the appended claims have been drafted without multiple dependencies, this has been done only to accommodate formal requirements in jurisdictions that do not allow such multiple dependencies. It should be noted that all possible combinations of features that would be implied by rendering the claims multiply dependent are explicitly envisaged and should be considered part of the invention.

It should be noted that the above-described examples, numbers used, and exemplary calculations are to assist in the description of this embodiment. Inadvertent typographical and mathematical errors do not detract from the utility and basic advantages of the invention.

It will be appreciated that the above descriptions are intended only to serve as examples, and that many other embodiments are possible within the scope of the present invention as defined in the appended claims.

What is claimed is:

1. A system comprising:
(a) an embedded buffer configured as part of a server, said embedded buffer including:
(i) a temporary storage buffer configured for intermediate storage of transactions;
(ii) a buffer management module configured for making decisions about subsequent read and write operations to said temporary storage buffer;
(iii) an arbitration module configured for arbitrating transactions between components of the server; and
(iv) signaling logic providing a handshake mechanism between elements of said embedded buffer and said components of the server.

2. The system of claim 1 wherein said server is a system on a chip (SoC).

3. The system of claim 1 wherein said embedded buffer is memory mapped to be accessible by said components of the server.

4. The system of claim 1 wherein said transactions come from sources internal or external to the server.

5. The system of claim 1 wherein said transactions are events.

6. The system of claim 1 wherein said temporary storage buffer includes at least two sub-buffers.

7. The system of claim 6 further including an event distributor/power manager (ED/PM) configured to control an active portion and sleeping portion of sub-buffers based on a current workload.

8. The system of claim 1 wherein said buffer management module is further configured for assisting with queuing and pre-fetching transactions based on operational rates of DRAM, disk, and/or network.

9. The system of claim 1 wherein components are selected from a group consisting of:
(a) CPU;
(b) SATA;
(c) NIC;
(d) DMA; and
(e) network ports.

10. They system of claim 1 wherein said buffer management module and/or said arbitration module are configured to use said signaling logic for control selected from the group consisting of:
(a) avoiding overrun conditions in said temporary storage buffer;
(b) avoiding underrun conditions in said temporary storage buffer;
(c) controlling flow of PCIe; and
(d) controlling flow of Ethernet.

11. A method comprising the steps of:
(a) storing transactions in a temporary storage buffer configured in an embedded buffer on a server;
(b) deciding to make subsequent read and write operations to said temporary storage buffer based on parameters selected from, but not limited to, a group consisting of:
(i) operational rates of DRAM;
(ii) operational rates of one or more disks; and
(iii) operational rates of one or more networks,
(c) arbitrating transactions between components of the server; and
(d) providing signaling logic configured as a handshake mechanism between elements of said embedded buffer and said components of the server.

12. The method of claim 11 wherein said embedded buffer is memory mapped to be accessible by said components of the server.

13. The method of claim 11 wherein said transactions come from sources internal or external to the server.

14. The method of claim 11 wherein said transactions are events.

15. The method of claim 11 wherein said temporary storage buffer includes at least two sub-buffers and further including the step of:
(e) controlling an active portion and sleeping portion of sub-buffers based on a current workload.

16. The method of claim 11 wherein the step of deciding to make subsequent read and write operations further includes assisting with queuing and pre-fetching transactions.

17. The method of claim 11 wherein components are selected from a group consisting of:
(a) CPU;
(b) SATA;
(c) NIC;
(d) DMA; and
(e) network ports.

18. They method of claim 11 wherein said deciding to make subsequent read and write operations uses said signaling logic for control selected from the group consisting of:
(a) avoiding overrun conditions in said temporary storage buffer;
(b) avoiding underrun conditions in said temporary storage buffer;
(c) controlling flow of PCIe; and
(d) controlling flow of Ethernet.

19. A computer-readable storage medium having embedded thereon computer-readable code, the computer-readable code comprising program code for:
(a) storing transactions in a temporary storage buffer configured in an embedded buffer on a server;
(b) deciding to make subsequent read and write operations to said temporary storage buffer based on parameters selected from, but not limited to, a group consisting of:
(i) operational rates of DRAM;
(ii) operational rates of one or more disks; and
(iii) operational rates of one or more networks,
(c) arbitrating transactions between components of the server; and
(d) providing signaling logic configured as a handshake mechanism between elements of said embedded buffer and said components of the server.
